(19) United States
(12) Patent Application Publication
(10) Pub. No.: US 2019/0013334 A1
(43) Pub. Date: Jan. 10, 2019

(54) MANUFACTURING METHOD FOR ARRAY SUBSTRATE

(71) Applicant: SHENZHEN CHINA STAR OPTOELECTRONICS TECHNOLOGY CO., LTD., Shenzhen, Guangdong (CN)

(72) Inventor: Xiaobo HU, Shenzhen, Guangdong (CN)

(73) Assignee: Shenzhen China Star Optoelectronics Technology Co., Ltd., Shenzhen, Guangdong (CN)

(21) Appl. No.: 15/558,704

(22) PCT Filed: Aug. 11, 2017
(86) PCT No.: PCT/CN2017/097232

§ 371 Date: Sep. 15, 2017

(30) Foreign Application Priority Data
Jul. 5, 2017 (CN) 201710543887.2

(51) Int. Cl. H01L 27/12; H01L 29/24; H01L 29/786; H01L 29/66

(52) U.S. Cl. CPC H01L 27/127; H01L 27/1225; H01L 27/1288; H01L 29/24; G02F 1/1368; H01L 29/78633; H01L 29/78618; H01L 29/66969; H01L 29/7869

(57) ABSTRACT

The present disclosure discloses a method for manufacturing an array substrate comprising: forming a gate electrode on a substrate; forming a gate insulating layer on one side of the substrate facing the gate electrode, the gate insulating layer covering the gate electrode; depositing an indium gallium zinc tin oxide layer and an indium gallium zinc oxide layer on one side of the gate insulating layer away from the gate electrode; patterning the indium gallium zinc oxide layer and the indium gallium zinc tin oxide layer by a first yellow light process to form a protective layer and an active layer, the protective layer covering the active layer; depositing a metal layer on one side of the protective layer away from the active layer; and patterning the metal layer and the protective layer by a second yellow light process to form a source electrode, a drain electrode, and a separation region.

### CROSS REFERENCE TO RELATED APPLICATIONS

This application claims priority to Chinese Patent Application No. 201710543887.2, entitled “Manufacturing Method for Array Substrate”, filed on Jul. 5, 2017, the disclosure of which is incorporated herein by reference in its entirety.

### FIELD OF THE INVENTION

The present disclosure relates to the field of an array substrate, in particular to a method for manufacturing an array substrate.

### BACKGROUND OF THE INVENTION

With the development of display technology, flat display devices like liquid crystal display (LCD) having advantages of high picture quality, energy saving, slim design and wide range of applications, are widely used in mobile phones, televisions, personal digital assistants, digital cameras, laptops, desktop computers and other consumer electronics products, thereby becoming the predominant display devices.

Most of the liquid crystal display devices on the market are back light type liquid crystal displays, which comprise liquid crystal display panels and back light modules. A liquid crystal display panel is composed of a color filter (CF) substrate, a thin film transistor (TFT) array substrate, liquid crystal (LC) sandwiched between the color film substrate and the array substrate, and a sealant frame. Among them, the performance of the thin film transistors of the array substrate directly affects the display quality of the liquid crystal display panel.

A thin film transistor using indium gallium zinc oxide (IGZO) semiconductor is provided with high mobility, thereby reducing the power consumption and cost of the liquid crystal display panels, and improving the resolution of the liquid crystal display panels to achieve full HD, and even to ultra definition (4k*2k) level. For that reason, such thin film transistor has received extensive attention and has been widely used. However, as the indium gallium zinc oxide semiconductor is sensitive to most of the acidic etchant and is easily corroded during wet etching, resulting in poor performance of the device.

### SUMMARY OF THE INVENTION

The technical problem to be solved by the present disclosure is to provide a method for manufacturing an array substrate, the device performance of the array substrate formed by the method is excellent.

In order to achieve the above goal, the embodiments of the present disclosure adopt the following technical solutions.

The present disclosure provides a method for manufacturing an array substrate, comprising:
forming a gate electrode on a substrate;
forming a gate insulating layer on one side of the substrate facing the gate electrode, the gate insulating layer covering the gate electrode;
depositing an indium gallium zinc tin oxide layer and an indium gallium zinc oxide layer sequentially on one side of the gate insulating layer away from the gate electrode;
patterning the indium gallium zinc oxide layer and the indium gallium zinc tin oxide layer by a first yellow light process to form a protective layer and an active layer, the protective layer covering the active layer;
depositing a metal layer on one side of the protective layer away from the active layer; and
patterning the metal layer and the protective layer by a second yellow light process to form a source electrode, a drain electrode, and a separation region, the source electrode and the drain electrode being spaced apart from each other and being connected respectively to both ends of the active layer, the separation region being formed on the protective layer and being positioned between the source electrode and the drain electrode.

Hereinto, the protective layer further comprises a first portion and a second portion which are spaced apart from each other. The first portion is positioned between the source electrode and the active layer, while the second portion is positioned between the drain electrode and the active layer.

Hereinto, the method for manufacturing the array substrate further comprises: treating the indium gallium zinc oxide layer by a conductivity treatment to make the first portion and the second portion form an ohmic contact layer.

Hereinto, the conductivity treatment is one of a plasma treatment method, an ion implantation treatment method, an ultraviolet light irradiation treatment method and a microwave treatment method.

Hereinto, the thickness of the ohmic contact layer is less than or equal to 500 Å.

Hereinto, the thickness of the active layer is greater than or equal to 400 Å and is less than or equal to 1000 Å.

Hereinto, the second yellow light process comprises:
forming a photoresist on one side of the metal layer away from the protective layer by a photolithography process, and the photoresist comprising a first region and a second region which are spaced apart from each other, at least a portion of the protective layer being positioned between the first region and the second region.

Hereinto, the second yellow light process further comprises:
removing a portion of the metal layer and a portion of the protective layer that are not covered by the photoresist by a wet etching process to form the source electrode, the drain electrode and the separation region.

Hereinto, the over-etching amount of the wet etching process is greater than 20%.

Hereinto, the method for manufacturing the array substrate further comprises:
forming a passivation layer on one side of the source electrode away from the gate insulating layer, the passivation layer covering the source electrode, the drain electrode and the active layer simultaneously, the passivation layer being provided with a via hole for exposing a portion of the drain electrode; and
forming a pixel electrode on one side of the passivation layer away from the source electrode, the pixel electrode being connected to the drain electrode through the via hole.

Compared with the related art, the present disclosure has the following beneficial effects.

Since the method for manufacturing an array substrate can form the protective layer covering the active layer, the protective layer can prevent the metal layer from damaging the active layer when the metal layer is deposited. Thus, the manufacturing method for the array substrate can improve the device characteristics of the thin film transistor formed by it, such as high mobility, low power consumption, low cost, high resolution and the like.

### BRIEF DESCRIPTION OF THE DRAWINGS

In order to illustrate technical solutions of present disclosure more clearly, the drawings needed in the description of embodiments of present disclosure will be introduced briefly. Apparently, hereinafter described drawings are merely a portion of embodiments of present disclosure. For those skilled in the art, they can obtain other drawings on the base of these drawings without creative work.

FIG. 1 is a schematic view corresponding to the step S01 of a method for manufacturing an array substrate according to some embodiments of the present disclosure.

FIG. 2 is a schematic view corresponding to the step S02 of a method for manufacturing an array substrate according to some embodiments of the present disclosure.

FIG. 3 is a schematic view corresponding to the step S03 of a method for manufacturing an array substrate according to some embodiments of the present disclosure.

FIG. 4 is a schematic view corresponding to the step S04 of a method for manufacturing an array substrate according to some embodiments of the present disclosure.

FIG. 5 is a schematic view corresponding to the step S05 of a method for manufacturing an array substrate according to some embodiments of the present disclosure.

FIG. 6 is a schematic view corresponding to the step S061 of a method for manufacturing an array substrate according to some embodiments of the present disclosure.

FIG. 7 is a schematic view corresponding to the step S062 of a method for manufacturing an array substrate according to some embodiments of the present disclosure.

FIG. 8 is a schematic view corresponding to the step S07 of a method for manufacturing an array substrate according to some embodiments of the present disclosure.

FIG. 9 is a schematic view corresponding to the step S08 of a method for manufacturing an array substrate according to some embodiments of the present disclosure.

### DETAILED DESCRIPTION OF ILLUSTRATED EMBODIMENTS

In order to make those skilled in the art understand the technical solutions of present disclosure better, clear and complete, description of the technical solutions of present disclosure will be illustrated, which combined with the drawings of embodiments in present disclosure. Apparently, described embodiments are merely a portion of embodiments of present disclosure, rather than all of the embodiments. Base on the embodiments of present disclosure, all other embodiments obtained by those skilled in the art without creative work are considered to be encompassed within the scope of the present disclosure.

Besides, the following descriptions for the respective embodiments are specific embodiments capable of being implemented for illustrations of the present invention with referring to appended figures. For example, the terms of “up”, “down”, “front”, “rear”, “left”, “right”, “interior”, “exterior”, “side”, etcetera are merely directions of referring to appended figures. Therefore, the wordings of directions are employed for explaining and understanding the present invention, rather than indicating or implying that the device or element referred to must have a specific orientation, or be constructed and operated in a particular orientation, and therefore cannot be understood as the limitations of the present invention.

In the description of the invention, which needs explanation is that the terms “installation”, “connected”, “connection”, “arranged on” should be broadly understood unless those are clearly defined and limited, otherwise. For example, those can be a fixed connection, a detachable connection, or an integral connection; those can be a mechanical connection; those can be a direct connection, an indirect connection with an intermediary, or an internal connection of two elements. To those of ordinary skill in the art, the specific meaning of the above terminology in the present invention can be understood in the specific circumstances.

Besides, in the description of the present invention, unless with being indicated otherwise, “plurality” means two or more. In the present specification, the term “process” encompasses an independent process, as well as a process that cannot be clearly distinguished from another process but yet achieves the expected effect of the process of interest. Moreover, in the present specification, any numerical range expressed herein using “to” refers to a range including the numerical values before and after “to” as the minimum and maximum values, respectively. In figures, the same reference numbers will be used to refer to the same or similar parts.

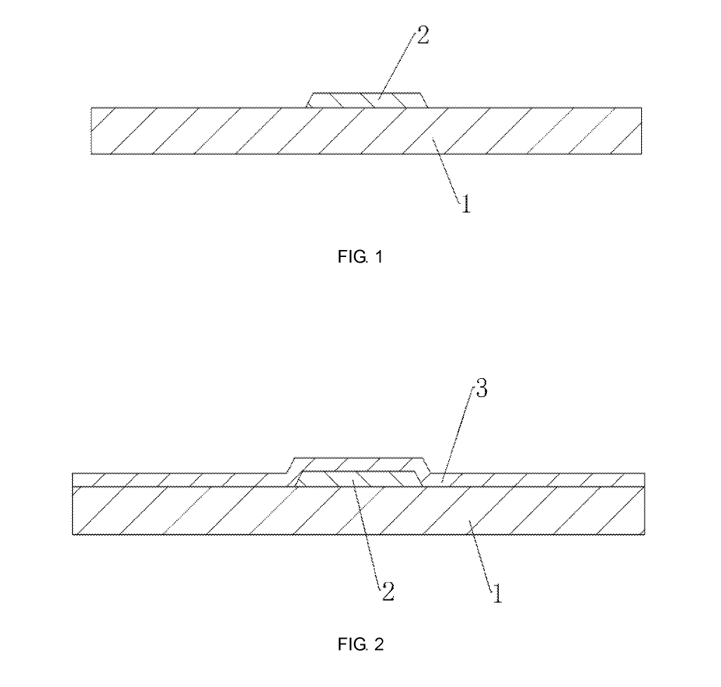

Referring to FIGS. 1 to 9, embodiments of the present disclosure provide a method for manufacturing an array substrate 100, which is applied to manufacturing the array substrate 100. The array substrate 100 can be applied to various display devices having a display panel. The display panel comprises an array substrate 100, a color filter substrate arranged opposite to the array substrate 100, and a liquid crystal layer sandwiched between the array substrate 100 and the color filter substrate.

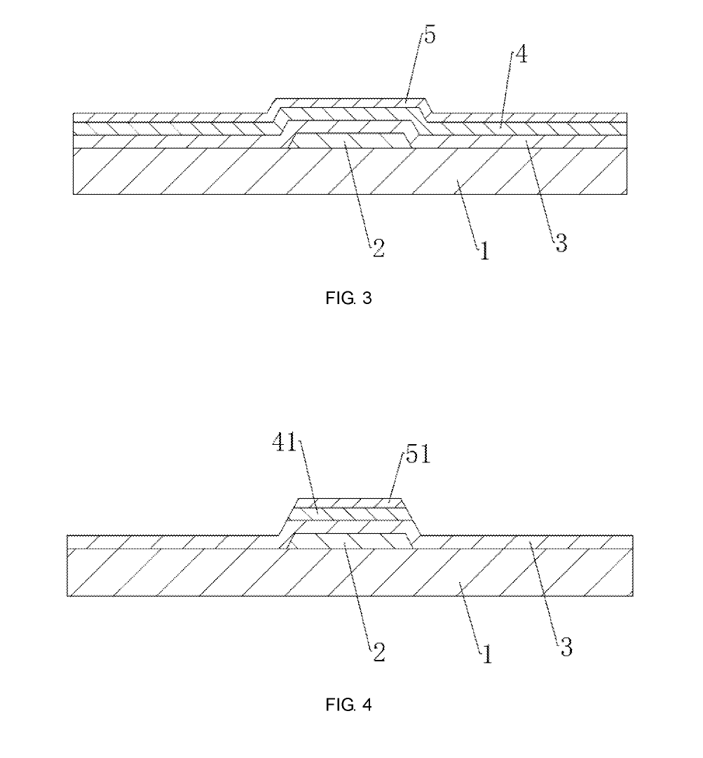

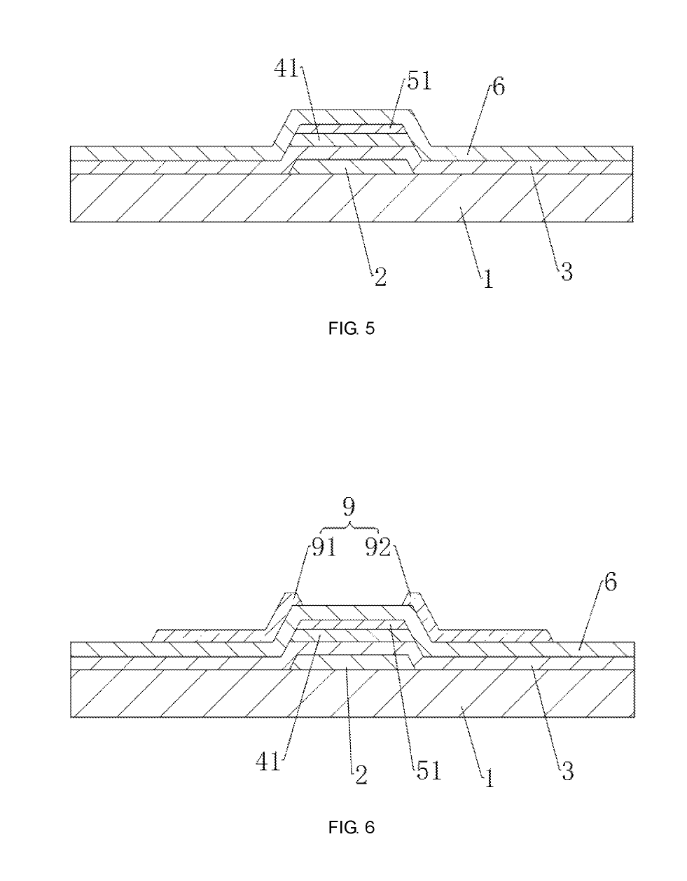

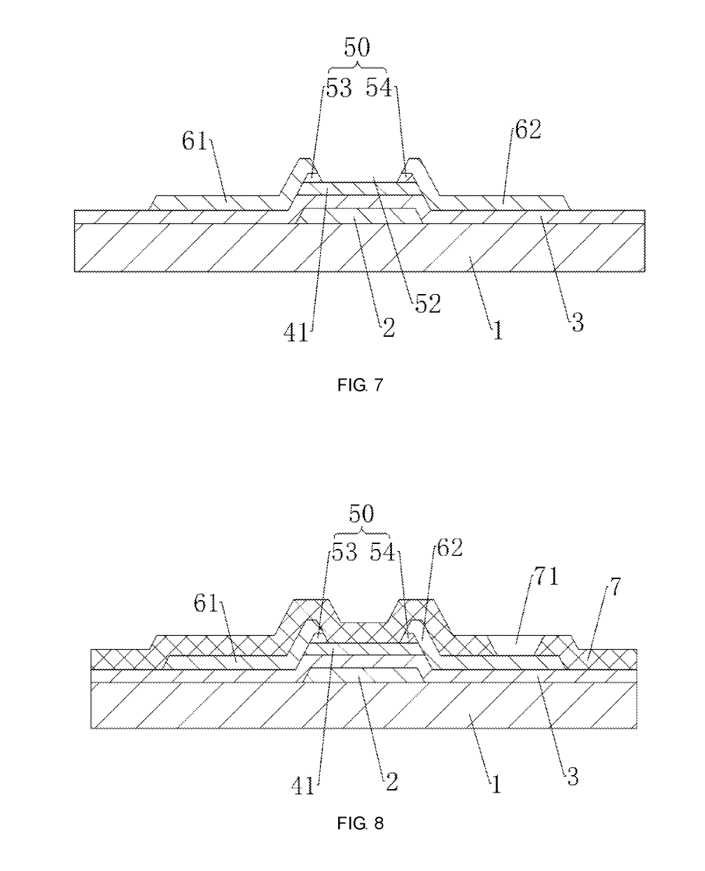

The method for manufacturing an array substrate 100 comprises:
S01, as shown in FIG. 1, forming a gate electrode 2 on a substrate 1;
S02, as shown in FIG. 2, forming a gate insulating layer 3 on one side of the substrate 1 facing the gate electrode 2, the gate insulating layer 3 covering the gate electrode 2;
S03, as shown in FIG. 3, depositing an indium gallium zinc tin oxide layer 4 (IGZTO) and an indium gallium zinc oxide layer 5 (IGZO) sequentially on one side of the gate insulating layer 3 away from the gate electrode 2;
S04, as shown in FIG. 4, patterning the indium gallium zinc oxide layer 5 and the indium gallium zinc tin oxide layer 4 by a first yellow light process to form a protective layer 51 and an active layer 41, the protective layer 51 covering the active layer 41, in this case, the active layer 41 being positioned between the gate insulating layer 3 and the protective layer 51, the active layer 41 being arranged facing to the gate electrode 2 directly;
S05, as shown in FIG. 5, depositing a metal layer 6 on one side of the protective layer 51 away from the active layer 41;
S06, as shown in FIGS. 6 and 7, patterning the metal layer 6 and the protective layer 51 by a second yellow light process to form a source electrode 61, a drain electrode 62, and a separation region 52, the source electrode 61 and the drain electrode 62 being spaced apart from each other and being connected respectively to both ends of the active layer 41, the separation region 52 being formed on the protective layer 51 and being positioned between the source electrode 61 and the drain electrode 62. In this case, the separation region 52 can be used to prevent direct electrical connection between the source electrode 61 and the drain electrode 62 through the protective layer 51.

In this embodiment, the array substrate 100 formed by the method for manufacturing the array substrate 100 comprises the gate electrode 2, the gate insulating layer 3, the active layer 41, the source electrode 61 and the drain electrode 62, which are used to form a thin film transistor (TFT) with a back channel etch type structure (BCE). Since the method for manufacturing an array substrate 100 can form the protective layer 51 covering the active layer 41, the protective layer 51 can prevent the metal layer 6 from damaging the active layer 41 when the metal layer 6 is deposited. Thus, the manufacturing method for the array substrate 100 can improve the device characteristics of the thin film transistor, such as high mobility, low power consumption, low cost, high resolution and the like.

Understandably, the yellow light process according to the present disclosure is a process of protecting the substrate by a residual part of a photosensitive substance, etching the substrate and finally obtaining a patterned structure. The residual part of the photosensitive substance is derived from the photosensitive material (also known as photoresist) coated on the surface of the substrate after being exposed and developed.

Optionally, in the step S01, the gate electrode 2 is formed by a third yellow light process. The gate electrode 2 is made of a metal material having excellent electrical conductivity and good light-shielding property. The gate electrode 2 is capable of blocking light to prevent light from entering the active layer 41 of the thin film transistor, so that the thin film transistor has good electrical stability and the array substrate 100 has good device performance. The material of the gate electrode 2 can be one or a stacked combination of molybdenum (Mo), aluminum (Al), copper (Cu), and titanium (Ti).

Optionally, the gate insulating layer 3 is made of a silicon oxide (SiO₂) material.

Optionally, in the step S03, the indium gallium zinc tin oxide layer 4 and the indium gallium zinc oxide layer 5 are deposited by a physical vapor deposition (PVD) method.

Optionally, the thickness of the active layer 41 is greater than or equal to 400 Å and is less than or equal to 1000 Å. When the thickness of the active layer 41 made of the indium gallium zinc tin oxide material satisfies the aforementioned conditions, the device performance of the thin film transistor is great. When the thickness of the active layer 41 is less than 400 Å or greater than 1000 Å, the device performance of the thin film transistor is gradually reduced.

Optionally, the source electrode 61 and the drain electrode 62 are both made of a stacked combination of aluminum (Al) and molybdenum (Mo).

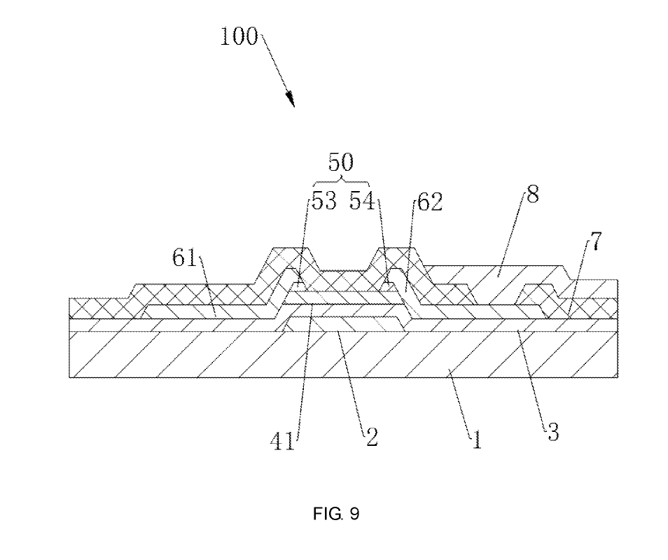

Referring to FIGS. 1 to 9, as an alternative embodiment, the method for manufacturing the array substrate 100 further comprises:
S07, as shown in FIG. 8, forming a passivation layer 7 (PV) on one side of the source electrode 61 away from the gate insulating layer 3, the passivation layer 7 covering the source electrode 61, the drain electrode 62 and the active layer 41 simultaneously, the passivation layer 7 being provided with a via hole 71 for exposing a portion of the drain electrode 62;
S08, as shown in FIG. 9, forming a pixel electrode 8 on one side of the passivation layer 7 away from the source electrode 61, the pixel electrode 8 being connected to the drain electrode 62 through the via hole 71.

Optionally, in the step S07, the passivation layer 7 is formed by a fourth yellow light process.

Optionally, in the step S08, the pixel electrode 8 is formed by a fifth yellow light process.

In this embodiment, the thin film transistor with metal oxide back channel etch type structure is produced by the manufacturing method of array substrate 100 with five yellow light processes (the third yellow light process, the first yellow light process, the second yellow light process, the fourth yellow light process, and the fifth light yellow process in turn), which requires only five mask processes. Compared with the manufacturing method of conventional metal oxide etch stop layer (ESL) type thin film transistor, the manufacturing method of the present disclosure reduces one mask process. Therefore, the process steps of the manufacturing method of the array substrate 100 are relatively simplified, and the cost is low.

Optionally, the passivation layer 7 is made of a silicon oxide (SiO₂) film or a composite film of silicon oxide (SiO₂) and silicon nitride (SiNx). The silicon oxide film is close to the active layer 41, and the silicon nitride film is remote from the active layer 41. The pixel electrode 8 is made of an indium tin oxide (ITO) material.

Referring to FIGS. 1 to 9, as an alternative embodiment, the protective layer 51 further comprises a first portion 53 and a second portion 54 which are spaced apart from each other, while the first portion 53 is positioned between the source electrode 61 and the active layer 41, the second portion 54 is positioned between the drain electrode 62 and the active layer 41. In this case, the separation region 52 is positioned between the first portion 53 and the second portion 54, the first portion 53 and the second portion 54 are connected respectively to both ends of the active layer 41.

In this embodiment, since the first portion 53 and the second portion 54 of the protective layer 51 are retained by the manufacturing method of the array substrate 100, the first portion 53 can prevent the connection structure between the source electrode 61 and the active layer 41 from being damaged due to excessive etching in the second yellow light process, thereby facilitating guaranteeing the connection reliability between the source electrode 61 and the active layer 41. The second portion 54 can prevent the connection structure between the drain electrode 62 and the active layer 41 from being damaged due to excessive etching in the second yellow light process, thereby facilitating guaranteeing the connection reliability between the drain electrode 62 and the active layer 41, so that the device characteristics of the array substrate 100 are excellent.

Optionally, the method for manufacturing the array substrate further comprises: treating the indium gallium zinc oxide layer 5 by a conductivity treatment to make the first portion 53 and the second portion 54 form an ohmic contact layer.

In this embodiment, the conductive indium gallium zinc oxide layer 5 has electrical conductivity, so that the first portion 53 and the second portion 54 formed by the indium gallium oxide layer 5 after patterning are electrically conductive, thereby forming the ohmic contact layer 50. Since the ohmic contact layer 50 has good electrical conductivity, it is advantageous for achieving good conductive contact between the source electrode 61 and the active layer 41 and good conductive contact between the drain electrode 62 and the active layer 41, which not only reduces the contact resistance between the source electrode 61 and the active layer 41 and the contact resistance between the drain electrode 62 and the active layer 41, but also reduces the risk of current leakage.

Understandably, the indium gallium zinc oxide layer 5 can be treated by the conductivity treatment between step S03 and step S04.

Optionally, the conductivity treatment is one of a plasma treatment method, an ion implantation treatment method, an ultraviolet light irradiation treatment method and a microwave treatment method.

Optionally, the thickness of the ohmic contact layer 50 is less than or equal to 500 Å. When the ohmic contact layer 50 made of the conductive indium gallium zinc oxide material satisfies the aforementioned conditions, the contact resistance between the source electrode 61 and the active layer 41 and the contact resistance between the drain electrode 62 and the active layer 41 can be effectively reduced.

Referring to FIGS. 1 to 9, as an alternative embodiment, the second yellow light process comprises:
S061, as shown in FIG. 6, forming a photoresist 9 on one side of the metal layer 6 away from the protective layer 51 by a photolithography process, and the photoresist 9 comprising a first region 91 and a second region 92 which are spaced apart from each other, at least a portion of the protective layer 51 being positioned between the first region 91 and the second region 92.

In one embodiment, a portion of the protective layer 51 is positioned between the first region 91 and the second region 92. In this case, the portion of the protective layer 51 positioned between the first region 91 and the second region 92 is not covered by the photoresist 9, the portion of the protective layer 51 corresponds to the separation region 52 formed after etching. The metal layer 6 covered by the first region 91 corresponds to the source electrode 61 formed after etching, the first region 91 covers the first portion 53 formed after etching. The metal layer 6 covered by the second region 92 corresponds to the drain 62 formed after etching, and the second region 92 covers the second portion 54 formed after etching.

In another embodiment, the entire protective layer 51 is positioned between the first region 91 and the second region 92. In this case, the entire protective layer 51 is not covered by the photoresist 9 and is completely etched away in the subsequent step to form the separation region 52.

Optionally, the second yellow light process further comprises:
S062, as shown in FIG. 7, removing a portion of the metal layer 6 and a portion of the protective layer 51 that are not covered by the photoresist 9 by a wet etching process to form the source electrode 61, the drain electrode 62 and the separation region 52.

In this embodiment, the indium gallium zinc tin oxide material and the indium gallium zinc oxide material have different solubility in the acidic etchant, so that the metal layer 6, the protective layer 51 and the active layer 41 have difference in the wet etching process, thereby patterning the metal layer 6 and the protective layer 51 which are easily soluble in the acidic etchant to form the source electrode 61, the drain electrode 62, and the separation region 52. At the same time, the active layer 41 which does not dissolve in the acid etchant can be prevented from being corroded, which may otherwise make the device defective, thereby ensuring good device performance of the array substrate 100.

Optionally, the wet etching process can use an acidic etchant containing aluminum (Al).

Optionally, prior to step S062, the residual photoresist 9 is removed by an ashing treatment to ensure the yield of subsequent process steps.

Optionally, the over-etching amount of the wet etching process is greater than 20%, so that the portion of the protective layer 51 positioned between the source electrode 61 and the drain electrode 62 can be completely etched away to form a qualified separation region 52, thereby improving the product yield of the manufacturing method of the array substrate 100.

It is to be understood that the foregoing description merely depicts some exemplary embodiments of the disclosure for the sole purpose of illustrating the principles of the disclosure, but the disclosure is not limited thereto. It would be apparent to those skilled in the art that various changes and modifications can be made therein without departing from the scope of the disclosure, and all these changes or modifications shall be considered to fall within the protection of the disclosure.

What is claimed is:

1. A method for manufacturing an array substrate, comprising:
forming a gate electrode on a substrate;
forming a gate insulating layer on one side of the substrate facing the gate electrode, the gate insulating layer covering the gate electrode;
depositing an indium gallium zinc tin oxide layer and an indium gallium zinc oxide layer sequentially on one side of the gate insulating layer away from the gate electrode;
patterning the indium gallium zinc oxide layer and the indium gallium zinc tin oxide layer by a first yellow light process to form a protective layer and an active layer, the protective layer covering the active layer;
depositing a metal layer on one side of the protective layer away from the active layer; and
patterning the metal layer and the protective layer by a second yellow light process to form a source electrode, a drain electrode, and a separation region, the source electrode and the drain electrode being spaced apart from each other and being connected respectively to both ends of the active layer, the separation region being formed on the protective layer and being positioned between the source electrode and the drain electrode.

2. The method for manufacturing an array substrate according to claim 1, wherein the protective layer further comprising a first portion and a second portion which are spaced apart from each other, the first portion being positioned between the source electrode and the active layer, the second portion being positioned between the drain electrode and the active layer.

3. The method for manufacturing an array substrate according to claim 2, wherein the method for manufacturing the array substrate further comprises: treating the indium gallium zinc oxide layer by a conductivity treatment to make the first portion and the second portion form an ohmic contact layer.

4. The method for manufacturing an array substrate according to claim 3, wherein the conductivity treatment is one of a plasma treatment method, an ion implantation treatment method, an ultraviolet light irradiation treatment method and a microwave treatment method.

5. The method for manufacturing an array substrate according to claim 3, wherein the thickness of the ohmic contact layer is less than or equal to 500 Å.

6. The method for manufacturing an array substrate according to claim 1, wherein the thickness of the active layer is greater than or equal to 400 Å and is less than or equal to 1000 Å.

7. The method for manufacturing an array substrate according to claim 1, wherein the second yellow light process comprises: forming a photoresist on one side of the metal layer away from the protective layer by a photolithography process, and the photoresist comprising a first region and a second region which are spaced apart from each other, at least a portion of the protective layer being positioned between the first region and the second region.

8. The method for manufacturing an array substrate according to claim 7, wherein the second yellow light process further comprises: removing a portion of the metal layer and a portion of the protective layer that are not covered by the photoresist by a wet etching process to form the source electrode, the drain electrode and the separation region.

9. The method for manufacturing an array substrate according to claim 8, wherein the over-etching amount of the wet etching process is greater than 20%.

10. The method for manufacturing an array substrate according to claim 2, wherein the second yellow light process comprises: forming a photoresist on one side of the metal layer away from the protective layer by a photolithography process, and the photoresist comprising a first region and a second region which are spaced apart from each other, at least a portion of the protective layer being positioned between the first region and the second region.

11. The method for manufacturing an array substrate according to claim 10, wherein the second yellow light process further comprises: removing a portion of the metal layer and a portion of the protective layer that are not covered by the photoresist by a wet etching process to form the source electrode, the drain electrode and the separation region.

12. The method for manufacturing an array substrate according to claim 11, wherein the over-etching amount of the wet etching process is greater than 20%.

13. The method for manufacturing an array substrate according to claim 3, wherein the second yellow light process comprises: forming a photoresist on one side of the metal layer away from the protective layer by a photolithography process, and the photoresist comprising a first region and a second region which are spaced apart from each other, at least a portion of the protective layer being positioned between the first region and the second region.

14. The method for manufacturing an array substrate according to claim 13, wherein the second yellow light process further comprises: removing a portion of the metal layer and a portion of the protective layer that are not covered by the photoresist by a wet etching process to form the source electrode, the drain electrode and the separation region.

15. The method for manufacturing an array substrate according to claim 14, wherein the over-etching amount of the wet etching process is greater than 20%.

16. The method for manufacturing an array substrate according to claim 4, wherein the second yellow light process comprises: forming a photoresist on one side of the metal layer away from the protective layer by a photolithography process, and the photoresist comprising a first region and a second region which are spaced apart from each other, at least a portion of the protective layer being positioned between the first region and the second region.

17. The method for manufacturing an array substrate according to claim 6, wherein the second yellow light process comprises: forming a photoresist on one side of the metal layer away from the protective layer by a photolithography process, and the photoresist comprising a first region and a second region which are spaced apart from each other, at least a portion of the protective layer being positioned between the first region and the second region.

18. The method for manufacturing an array substrate according to claim 1, wherein the method for manufacturing the array substrate further comprises:
forming a passivation layer on one side of the source electrode away from the gate insulating layer, the passivation layer covering the source electrode, the drain electrode and the active layer simultaneously, the passivation layer being provided with a via hole for exposing a portion of the drain electrode; and
forming a pixel electrode on one side of the passivation layer away from the source electrode, the pixel electrode being connected to the drain electrode through the via hole.

19. The method for manufacturing an array substrate according to claim 2, wherein the method for manufacturing the array substrate further comprises:
forming a passivation layer on one side of the source electrode away from the gate insulating layer, the passivation layer covering the source electrode, the drain electrode and the active layer simultaneously, the passivation layer being provided with a via hole for exposing a portion of the drain electrode; and
forming a pixel electrode on one side of the passivation layer away from the source electrode, the pixel electrode being connected to the drain electrode through the via hole.

20. The method for manufacturing an array substrate according to claim 3, wherein the method for manufacturing the array substrate further comprises:
forming a passivation layer on one side of the source electrode away from the gate insulating layer, the passivation layer covering the source electrode, the drain electrode and the active layer simultaneously, the passivation layer being provided with a via hole for exposing a portion of the drain electrode; and
forming a pixel electrode on one side of the passivation layer away from the source electrode, the pixel electrode being connected to the drain electrode through the via hole.
